(19) United States
(12) Patent Application Publication
(10) Pub. No.: US 2012/0012355 A1
(43) Pub. Date: Jan. 19, 2012

(54) SHELL OF ELECTRONIC DEVICE

(75) Inventors: HONG LI, Shenzhen City (CN); TING-TING ZHAO, Shenzhen City (CN); NA WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/891,877

(22) Filed: Sep. 28, 2010

(30) Foreign Application Priority Data
Jul. 19, 2010 (CN) 201010231192.9

(51) Int. Cl. H05K 5/00

(52) U.S. Cl. 174/50

(57) ABSTRACT

A shell of an electronic device includes an inner surface and an outer surface opposite to the inner surface. The inner surface defines at least one recessed portion. The at least one recessed portion includes a bottom surface and a transition surface connecting the bottom surface with the inner surface.

### BACKGROUND

1. Technical Field

The present disclosure relates to electronic devices, and particularly to a shell of an electronic device.

2. Description of Related Art

With the electronics industry drive towards further miniaturization, shells of electronic devices become thinner, and the density of components arranged inside the devices increases. Sometimes, because of design constraints, portions of the shells may be made thinner than other portions resulting in flimsy areas in the shell that are easily warped and damaged. Additionally, the shells are so flimsy they may even be damaged during the molding process.

Therefore, there is room for improvement in the art.

### BRIEF DESCRIPTION OF THE DRAWINGS

The components of the drawings are not necessarily drawn to scale, the emphasis instead being placed upon clearly illustrating the principles of the embodiments of the shell of an electronic device. Moreover, in the drawings, like reference numerals designate corresponding parts throughout several views.

FIG. 1 is a perspective view of a shell of an electronic device in accordance with one embodiment.

FIG. 2 is an enlarged sectional view of circled portion II in FIG. 1.

FIG. 3 is a cross-sectional view taken along line of FIG. 2.

### DETAILED DESCRIPTION

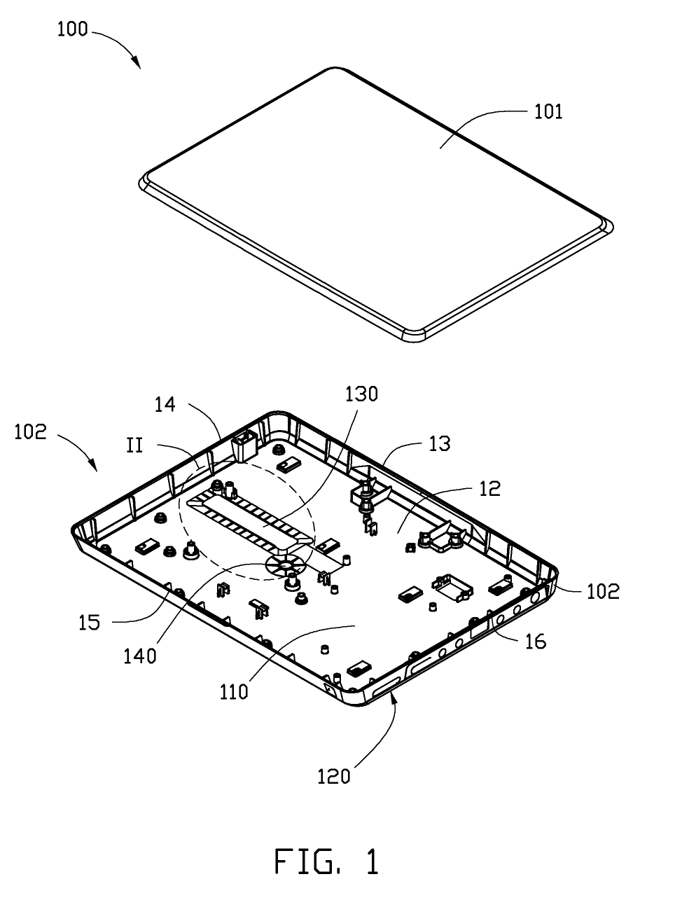

Referring to FIG. 1, a shell 100 of an electronic device is shown. The shell 100 includes a front portion 101, and a rear portion 102. The shell 100 can be made of plastic, metal, or other material. In the embodiment, the shell 100 is used for a portable DVD player. For, simplicity, the rear portion 102 is taken for exemplifying the present disclosure.

The rear portion 102 includes a rectangular base 12, and four sidewalls (hereinafter, a first sidewall 13, a second sidewall 14, a third sidewall 15, and a fourth sidewall 16) protruding from four rims of the base 12. The first sidewall 13, the second sidewall 14, the third sidewall 15 opposite to the first sidewall 13, and the fourth sidewall 16 opposite to the second sidewall 14 are serially interconnected with each other to define an accommodating space (not labeled) to receive components (not shown) of the electronic device, e.g., a circuit board, a motor, an optical head and so on.

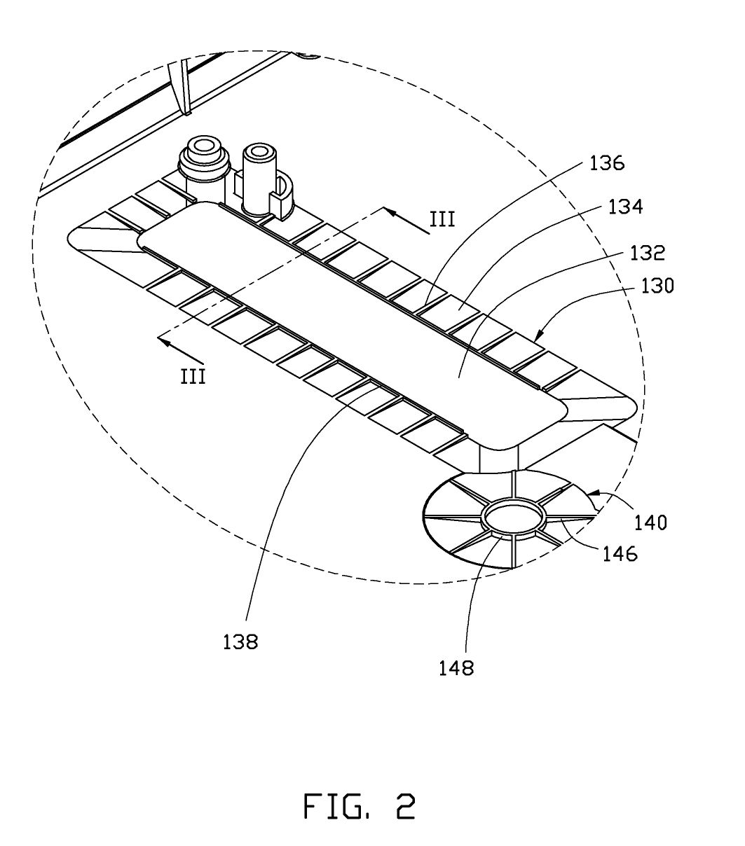

The base 12 includes an inner surface 110 and an outer surface 120. The outer surface 120 is opposite and parallel to the inner surface 110. Both the inner surface 110 and the outer surface 120 are flat. Two portions of the inner surface 110 are partially cut away to form two recessed portions (hereinafter, a first recessed portion 130 and a second recessed portion 140 (shown in FIG. 2)). In the embodiment, the first recessed portion 130 is substantially rectangular and provides space for the optical head. The second recessed portion 140 is substantially round and provides space for the motor. It is noteworthy that the number, the shape, and the size of the first and second recessed portions 130, 140 may be changed according to need.

For clarity, in the following, the first recessed portion 130 and the corresponding optical head are described for better explaining the embodiment.

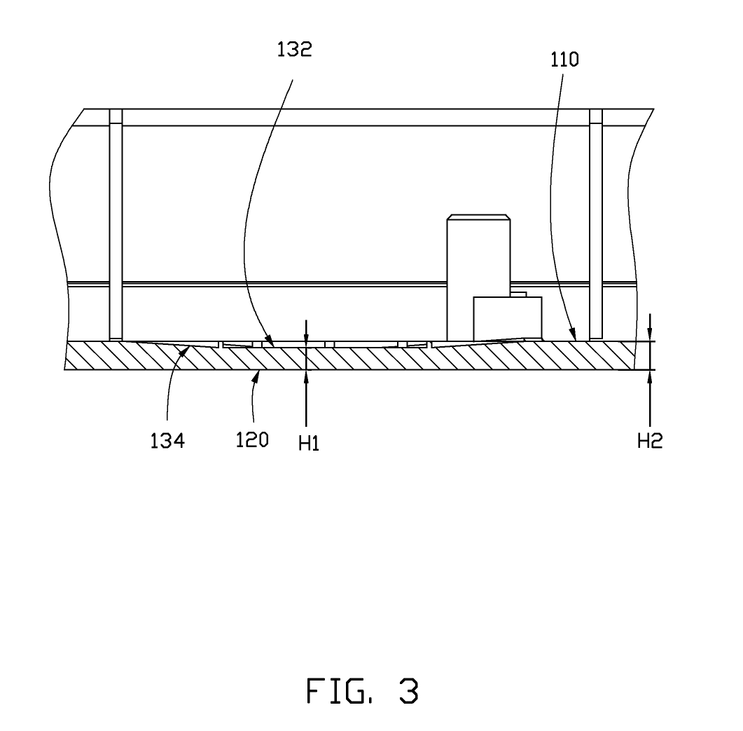

Referring also to FIGS. 2-3, the first recessed portion 130 includes a bottom surface 132. The bottom surface 132 is parallel to and sandwiched by the inner surface 110 and the outer surface 120, thus, the distance H1 between the bottom surface 132 and outer surface 120 is less than the distance H2 between the inner surface 110 and the outer surface 120. The first recessed portion 130 further includes a transition surface 134 connecting the bottom surface 132 with the inner surface 110. The transition surface 134 extends smoothly and aslant from the bottom surface 132 to the inner surface 110. It is noteworthy that, when the rear portion 102 is molded (not shown), a portion of the mold corresponding to the transition surface 134 is configured smooth and set at an angle to assure that the first recessed portion 130 extends smoothly from the bottom surface 132 to the inner surface 110. Furthermore, because the portion of the mold corresponding to the first recessed portion 130 are arranged smoothly and aslant, the plastic for forming the rear portion 102 flows easily into the mold during molding of the rear portion 102. As a result, flow defects caused by the plastic flowing badly in the mold are avoided.

A plurality of reinforcing ribs 136 are arranged equidistantly spaced from each other on the transition surface 134, to reinforce the rear portion 102 surrounding the first recessed portion 130. Additionally, because of the arranged reinforcing rib 136, the mold holds the rear portion 102 better during the manufacturing process to protect the rear portion 102 from deformation.

Referring to FIG. 2, two strip-shaped stopping members 138 are arranged at two opposite lengthwise rim portions of the bottom surface 132 of the first recessed portion 130 respectively, and a round stopping member 148 is arranged at the rim of the second recessed portion 140. One end of the reinforcing ribs 136, 146 are coupled to the corresponding stopping members 138,148 respectively. The stopping members 138, 148 are used to reinforce the corresponding first and second recessed portions 130, 140, and are also used to limit movement of the components of the electronic device mounted therein.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A shell of an electronic device, comprising:
an inner surface; and
an outer surface opposite to the inner surface;
wherein the inner surface defines at least one recessed portion, the at least one recessed portion comprising a bottom surface and a transition surface connecting the bottom surface with the inner surface.

2. The shell of claim 1, wherein the inner and outer surfaces are flat, the bottom surface of the at least one recessed portion is parallel to the inner surface.

3. The shell of claim 2, wherein the outer surface are parallel to the inner surface.

4. The shell of claim 1, wherein a plurality of reinforcing ribs are arranged on the transition surface.

5. The shell of claim 4, wherein each reinforcing ribs extends from a rim of the bottom surface to the inner surface.

6. The shell of claim 5, wherein the plurality of reinforcing ribs are arranged equidistantly spaced from each other on the transition surface.

7. The shell of claim 1, wherein the shell is used in a DVD player, the inner surface defining the at least one recessed portion defines a rectangular recessed portion providing space for an optical head and a round recessed portion providing space for a motor.

8. The shell of claim 7, wherein the shell is made of plastic material.

9. An electronic device, comprising:
a shell;
wherein the shell comprises two opposite surfaces, one of the surfaces recesses inwardly to define at least one recessed portion, the at least one recessed portion comprises a bottom surface and a transition surface connecting the bottom surface with the one of the surface defining the at least one recessed portion.

10. The electronic device of claim 9, wherein the surfaces are flat, the bottom surface of the at least one recessed portion is parallel to the one of the surfaces defining the at least one recessed portion.

11. The electronic device of claim 10, wherein the surfaces are parallel to each other.

12. The electronic device of claim 9, wherein a plurality of reinforcing ribs are arranged equidistantly spaced from each other on the transition surface.

13. The electronic device of claim 12, wherein each reinforcing rib extends from a rim of the bottom surface to the one of the surfaces defining the at least one recessed portion.

14. The electronic device of claim 13, wherein the plurality of reinforcing ribs are arranged equally on the transition surface.

15. The electronic device of claim 9, wherein the shell is used in a DVD player, the one of the surfaces defining the at least one recessed portion defines a rectangular recessed portion providing space an optical head and a round recessed portion providing space a motor.

16. The electronic device of claim 15, wherein the shell is made of plastic material.
